(19) United States
(12) Patent Application Publication
(10) Pub. No.: US 2025/0280598 A1
(43) Pub. Date: Sep. 4, 2025

(54) SEMICONDUCTOR DEVICE AND SEMICONDUCTOR MEMORY DEVICE

(71) Applicant: Kioxia Corporation, Tokyo (JP)

(72) Inventors: Kasumi YASUDA, Yokohama (JP); Masayasu MIYATA, Kawasaki (JP)

(73) Assignee: Kioxia Corporation, Tokyo (JP)

(21) Appl. No.: 18/885,855

(22) Filed: Sep. 16, 2024

(30) Foreign Application Priority Data
Mar. 4, 2024 (JP) 2024-032142

(51) Int. Cl. H01L 27/092; H01L 29/423; H01L 29/49; H01L 29/51

(52) U.S. Cl. CPC H10D 84/85; H10D 64/517; H10D 64/666; H10D 64/691

(57) ABSTRACT

A semiconductor device of embodiments includes: an n-channel MOSFET including a first gate insulating film and a first gate electrode, the first gate electrode including a first region containing Ti and Al and a second region provided between the first gate insulating film and the first region, in contact with the first gate insulating film, and containing a first metal element and nitrogen (N); and a p-channel MOSFET including a second gate insulating film and a second gate electrode, the second gate electrode including a third region containing Ti and Al, a fourth region provided between the second gate insulating film and the third region, in contact with the second gate insulating film, and containing the first metal element and nitrogen (N), and a fifth region provided between the third region and the fourth region and containing nitrogen (N) and a second metal element of Hf or Zr.

### CROSS-REFERENCE TO RELATED APPLICATION

This application is based upon and claims the benefit of priority from Japanese Patent Application No. 2024-032142, filed on Mar. 4, 2024, the entire contents of which are incorporated herein by reference.

### FIELD

Embodiments described herein relate generally to a semiconductor device and a semiconductor memory device.

### BACKGROUND

In a semiconductor device including an n-channel metal oxide semiconductor field effect transistor (MOSFET) and a p-channel MOSFET, it is desirable to control the threshold voltage of the n-channel MOSFET and the threshold voltage of the p-channel MOSFET to desired threshold voltages.

### BRIEF DESCRIPTION OF THE DRAWINGS

FIG. 1 is a schematic cross-sectional view of a semiconductor device according to a first embodiment;

FIG. 2 is a diagram showing a method for manufacturing the semiconductor device according to the first embodiment;

FIG. 3 is a diagram showing a method for manufacturing the semiconductor device according to the first embodiment;

FIG. 4 is a diagram showing a method for manufacturing the semiconductor device according to the first embodiment;

FIG. 5 is a diagram showing a method for manufacturing the semiconductor device according to the first embodiment;

FIG. 6 is a diagram showing a method for manufacturing the semiconductor device according to the first embodiment;

FIG. 7 is a diagram showing a method for manufacturing the semiconductor device according to the first embodiment;

FIG. 8 is a schematic cross-sectional view of a semiconductor device according to a first comparative example;

FIG. 9 is a schematic cross-sectional view of a semiconductor device according to a second comparative example;

FIG. 10 is an explanatory diagram of the function and effect of the semiconductor device according to the first embodiment;

FIG. 11 is an explanatory diagram of the function and effect of the semiconductor device according to the first embodiment;

FIG. 12 is a schematic cross-sectional view of a semiconductor device according to a second embodiment;

FIG. 13 is a schematic cross-sectional view of a semiconductor device according to a third embodiment; and

FIG. 14 is a schematic cross-sectional view of a semiconductor memory device according to a fourth embodiment.

### DETAILED DESCRIPTION

A semiconductor device of embodiments includes: an n-channel MOSFET including a first gate insulating film and a first gate electrode, the first gate electrode including a first region and a second region, the second region provided between the first gate insulating film and the first region and in contact with the first gate insulating film, the first region containing titanium (Ti) and aluminum (Al), and the second region containing a first metal element and nitrogen (N); and a p-channel MOSFET including a second gate insulating film and a second gate electrode, the second gate electrode including a third region, a fourth region, and a fifth region, the fourth region provided between the second gate insulating film and the third region and in contact with the second gate insulating film, the fifth region provided between the third region and the fourth region, the third region containing titanium (Ti) and aluminum (Al), the fourth region containing the first metal element and nitrogen (N), and the fifth region containing nitrogen (N) and a second metal element being at least one of hafnium (Hf) and zirconium (Zr).

Hereinafter, embodiments will be described with reference to the diagrams. In addition, in the following description, the same or similar members and the like are denoted by the same reference numerals, and the description of the members and the like once described may be omitted as appropriate.

In addition, in this specification, the term “upper” or “lower” may be used for convenience. “Upper” or “lower” is a term indicating the relative positional relationship in the diagram, but is not a term that defines the positional relationship with respect to gravity.

The qualitative analysis and quantitative analysis of the chemical composition of members forming the semiconductor device and the semiconductor memory device in this specification can be performed by, for example, secondary ion mass spectrometry (SIMS), energy dispersive X-ray spectroscopy (EDX), and Rutherford back-scattering spectroscopy (RBS). In addition, when measuring the thickness of each member forming the semiconductor device and the semiconductor memory device, a distance between members, a crystal particle size, and the like, it is possible to use, for example, a transmission electron microscope (TEM).

### First Embodiment

A semiconductor device according to a first embodiment includes an n-channel MOSFET including a first gate insulating film and a first gate electrode and a p-channel MOSFET including a second gate insulating film and a second gate electrode. The first gate electrode includes a first region containing titanium (Ti) and aluminum (Al) and a second region provided between the first gate insulating film and the first region, in contact with the first gate insulating film, and containing a first metal element and nitrogen (N). The second gate electrode includes a third region containing titanium (Ti) and aluminum (Al), a fourth region provided between the second gate insulating film and the third region, in contact with the second gate insulating film, and containing the first metal element and nitrogen (N), and a fifth region provided between the third region and the fourth region and containing nitrogen (N) and at least one second metal element of hafnium (Hf) and zirconium (Zr).

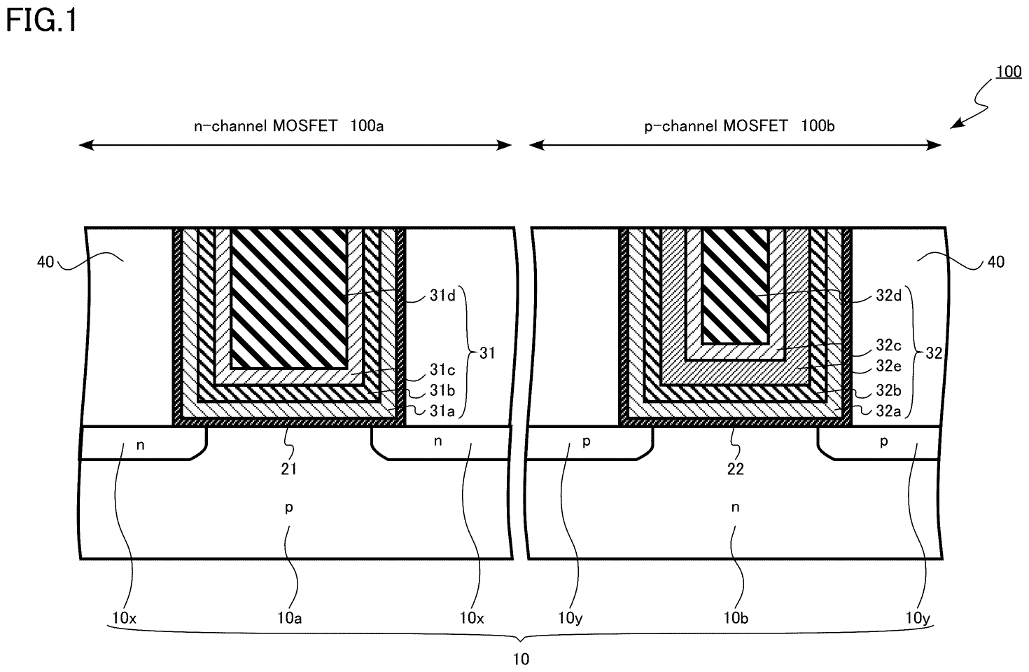

FIG. 1 is a schematic cross-sectional view of the semiconductor device according to the first embodiment.

The semiconductor device according to the first embodiment is a complementary metal oxide semiconductor (CMOS) semiconductor device 100.

The CMOS semiconductor device 100 includes an n-channel MOSFET 100a and a p-channel MOSFET 100b. The n-channel MOSFET 100a is a field effect transistor that uses electrons as carriers. The p-channel MOSFET 100b is a field effect transistor that uses holes as carriers. In addition, the n-channel MOSFET 100a and the p-channel MOSFET 100b use a so-called metal gate electrode in which a metal material is used for a gate electrode.

The CMOS semiconductor device 100 includes a CMOS circuit formed by, for example, the n-channel MOSFET 100a and the p-channel MOSFET 100b. The CMOS semiconductor device 100 includes, for example, a plurality of n-channel MOSFETs 100a and a plurality of p-channel MOSFETs 100b.

The n-channel MOSFET 100a includes a silicon substrate 10, a first gate insulating film 21, a first gate electrode 31, and an interlayer insulating layer 40. The silicon substrate 10 includes a p-well region 10a and a first source/drain region 10x. The first gate electrode 31 includes a first lower region 31a, a first intermediate region 31b, a first upper region 31c, and a first metal region 31d.

The silicon substrate 10 is an example of a semiconductor substrate. The first lower region 31a is an example of the second region. The first intermediate region 31b is an example of the sixth region. The first upper region 31c is an example of the first region.

The p-channel MOSFET 100b includes the silicon substrate 10, a second gate insulating film 22, a second gate electrode 32, and the interlayer insulating layer 40. The silicon substrate 10 includes an n-well region 10b and a second source/drain region 10y. The second gate electrode 32 includes a second lower region 32a, a second intermediate region 32b, a second upper region 32c, a second metal region 32d, and a barrier region 32e.

The second lower region 32a is an example of the fourth region. The second intermediate region 32b is an example of the seventh region. The second upper region 32c is an example of the third region. The barrier region 32e is an example of the fifth region.

The n-channel MOSFET 100a includes the silicon substrate 10, the first gate insulating film 21, the first gate electrode 31, and the interlayer insulating layer 40. The n-channel MOSFET 100a and the p-channel MOSFET 100b are formed using the same silicon substrate 10. The n-channel MOSFET 100a includes a first portion of the silicon substrate 10.

The p-well region 10a is p-type silicon. In addition, the first source/drain region 10x is n-type silicon. The p-well region 10a and the first source/drain region 10x are formed in the first portion of the silicon substrate 10.

The first gate insulating film 21 is provided on the silicon substrate 10. The first gate insulating film 21 is in contact with the silicon substrate 10. The first gate insulating film 21 is provided between the silicon substrate 10 and the first gate electrode 31. The first gate insulating film 21 faces the p-well region 10a and the first source/drain region 10x.

The first gate insulating film 21 is provided between the interlayer insulating layer 40 and the first gate electrode 31. The first gate insulating film 21 is in contact with the interlayer insulating layer 40.

The first gate insulating film 21 contains, for example, a material having a higher dielectric constant than silicon dioxide. The first gate insulating film 21 contains, for example, a High-k insulator. The first gate insulating film 21 is a so-called High-k gate insulating film.

The first gate insulating film 21 contains, for example, oxygen (0) and at least one element selected from a group consisting of hafnium (Hf), zirconium (Zr), tantalum (Ta), yttrium (Y), and titanium (Ti). The first gate insulating film 21 contains, for example, hafnium oxide, hafnium silicate, nitrogen incorporated hafnium silicate, nitrogen incorporated hafnium aluminate, zirconium oxide, tantalum oxide, yttrium oxide, or titanium oxide.

The film thickness of the first gate insulating film 21 is, for example, equal to or more than 1 nm and equal to or less than 10 nm. The equivalent oxide thickness of the first gate insulating film 21 is, for example, equal to or more than 0.5 nm and equal to or less than 2 nm.

The first gate insulating film 21 may have a stacked structure of a silicon oxide and a High-k insulator.

The first gate electrode 31 is provided on the first gate insulating film 21. The first gate electrode 31 is in contact with the first gate insulating film 21.

The first gate electrode 31 is formed by stacking, from the first gate insulating film 21 upward, the first lower region 31a, the first intermediate region 31b, the first upper region 31c, and the first metal region 31d in this order. The first lower region 31a is in contact with the first gate insulating film 21. The first intermediate region 31b is in contact with, for example, the first lower region 31a. The first upper region 31c is in contact with, for example, the first intermediate region 31b. The first metal region 31d is in contact with, for example, the first upper region 31c.

The first lower region 31a is provided between the first gate insulating film 21 and the first upper region 31c. The first lower region 31a is provided between the first gate insulating film 21 and the first intermediate region 31b. The first lower region 31a is provided on the first gate insulating film 21. The first lower region 31a is in contact with the first gate insulating film 21.

The first lower region 31a is electrically conductive. The first lower region 31a contains a first metal element and nitrogen (N). The first metal element is, for example, a transition metal element. The first metal element is, for example, at least one metal element selected from a group consisting of titanium (Ti), tantalum (Ta), vanadium (V), chromium (Cr), zirconium (Zr), niobium (Nb), hafnium (Hf), and tungsten (W).

The first lower region 31a contains, for example, titanium nitride, tantalum nitride, vanadium nitride, chromium nitride, zirconium nitride, niobium nitride, hafnium nitride, or tungsten nitride. The first lower region 31a is, for example, a titanium nitride, a tantalum nitride, a vanadium nitride, a chromium nitride, a zirconium nitride, a niobium nitride, a hafnium nitride, or a tungsten nitride.

The thickness of the first lower region 31a is, for example, equal to or more than 1 nm and equal to or less than 5 nm. In addition, in this specification, the thickness of each region is, for example, a thickness in a direction perpendicular to the surface of the silicon substrate 10.

The first lower region 31a is a region having a dominant effect on the threshold voltage of the n-channel MOSFET 100a.

The first intermediate region 31b is provided between the first upper region 31c and the first lower region 31a. The first intermediate region 31b is provided on the first lower region 31a. The first intermediate region 31b is in contact with, for example, the first lower region 31a.

The first intermediate region 31b is electrically conductive. The first intermediate region 31b contains a different material from the first lower region 31a.

The first intermediate region 31b contains a third metal element and nitrogen (N). The third metal element is different from the first metal element and the second metal element. The third metal element is, for example, a transition metal element. The third metal element is, for example, at least one metal element selected from a group consisting of titanium (Ti), tantalum (Ta), vanadium (V), chromium (Cr), zirconium (Zr), niobium (Nb), hafnium (Hf), and tungsten (W).

The first intermediate region 31b contains, for example, titanium nitride, tantalum nitride, vanadium nitride, chromium nitride, zirconium nitride, niobium nitride, hafnium nitride, or tungsten nitride. The first intermediate region 31b is, for example, a titanium nitride, a tantalum nitride, a vanadium nitride, a chromium nitride, a zirconium nitride, a niobium nitride, a hafnium nitride, or a tungsten nitride.

The thickness of the first intermediate region 31b is, for example, equal to or more than 1 nm and equal to or less than 5 nm.

The first intermediate region 31b functions as an etching stopper film when removing a film, which becomes the barrier region 32e of the p-channel MOSFET 100b, from the first gate electrode 31 during the manufacture of the n-channel MOSFET 100a, for example.

The first upper region 31c is provided between the first intermediate region 31b and the first metal region 31d. The first upper region 31c is provided on the first intermediate region 31b. The first upper region 31c is in contact with, for example, the first intermediate region 31b.

The first upper region 31c is electrically conductive. The first upper region 31c contains a different material from the first lower region 31a and the first intermediate region 31b.

The first upper region 31c contains titanium (Ti) and aluminum (Al). The first upper region 31c contains, for example, a titanium-aluminum alloy.

The thickness of the first upper region 31c is, for example, equal to or more than 1 nm and equal to or less than 8 nm.

The first upper region 31c has a function of lowering the threshold voltage of the n-channel MOSFET 100a when manufacturing the n-channel MOSFET 100a, for example.

The first metal region 31d is provided on the first upper region 31c. The first metal region 31d is in contact with, for example, the first upper region 31c. The first upper region 31c is provided between the first lower region 31a and the first metal region 31d.

The first metal region 31d is electrically conductive. The electric resistivity of the first metal region 31d is smaller than, for example, the electric resistivity of the first lower region 31a, the electric resistivity of the first intermediate region 31b, and the electric resistivity of the first upper region 31c.

The first metal region 31d contains a first metal. The first metal is, for example, at least one metal selected from a group consisting of aluminum (Al), tungsten (W), and molybdenum (Mo).

The first metal region 31d may have, for example, a stacked structure of a barrier metal film and a metal film. The barrier metal film is, for example, a titanium nitride. The metal film is, for example, aluminum, tungsten, or molybdenum.

The first metal region 31d has a function of reducing the gate resistance of the n-channel MOSFET 100a, for example.

The p-channel MOSFET 100b includes the silicon substrate 10, the second gate insulating film 22, the second gate electrode 32, and the interlayer insulating layer 40. The n-channel MOSFET 100a and the p-channel MOSFET 100b are formed using the same silicon substrate 10. The p-channel MOSFET 100b includes a second portion of the silicon substrate 10.

The n-well region 10b is n-type silicon. In addition, the second source/drain region 10y is p-type silicon. The n-well region 10b and the second source/drain region 10y are formed in the second portion of the silicon substrate 10.

The second gate insulating film 22 is provided on the silicon substrate 10. The second gate insulating film 22 is in contact with the silicon substrate 10. The second gate insulating film 22 is provided between the silicon substrate 10 and the second gate electrode 32. The second gate insulating film 22 faces the n-well region 10b and the second source/drain region 10y.

The second gate insulating film 22 is provided between the interlayer insulating layer 40 and the second gate electrode 32. The second gate insulating film 22 is in contact with the interlayer insulating layer 40.

The second gate insulating film 22 contains the same material as the first gate insulating film 21. The second gate insulating film 22 is formed of, for example, the same material as the first gate insulating film 21.

The second gate insulating film 22 contains, for example, a material having a higher dielectric constant than silicon dioxide. The second gate insulating film 22 contains, for example, a High-k insulator. The second gate insulating film 22 is a so-called High-k gate insulating film.

The second gate insulating film 22 contains, for example, oxygen (O) and at least one element selected from a group consisting of hafnium (Hf), zirconium (Zr), tantalum (Ta), yttrium (Y), and titanium (Ti). The second gate insulating film 22 contains, for example, hafnium oxide, hafnium silicate, nitrogen incorporated hafnium silicate, nitrogen incorporated hafnium aluminate, zirconium oxide, tantalum oxide, yttrium oxide, or titanium oxide.

The thickness of the second gate insulating film 22 is, for example, equal to or more than 1 nm and equal to or less than 10 nm. The equivalent oxide thickness of the second gate insulating film 22 is, for example, equal to or more than 0.5 nm and equal to or less than 2 nm.

The second gate insulating film 22 may have a stacked structure of a silicon oxide and a High-k insulator.

The second gate electrode 32 is provided on the second gate insulating film 22. The second gate electrode 32 is in contact with the second gate insulating film 22.

The second gate electrode 32 is formed by stacking, from the second gate insulating film 22 upward, the second lower region 32a, the second intermediate region 32b, the barrier region 32e, the second upper region 32c, and the second metal region 32d in this order. The second lower region 32a is in contact with the second gate insulating film 22. The second intermediate region 32b is in contact with, for example, the second lower region 32a. The barrier region 32e is in contact with, for example, the second intermediate region 32b. The second upper region 32c is in contact with, for example, the barrier region 32e. The second metal region 32d is in contact with, for example, the second upper region 32c.

The stacked structure of the second gate electrode 32 is different from that of the first gate electrode 31 in that the stacked structure of the second gate electrode 32 includes the barrier region 32e.

The second lower region 32a is provided between the second gate insulating film 22 and the second upper region 32c. The second lower region 32a is provided between the second gate insulating film 22 and the second intermediate region 32b. The second lower region 32a is provided on the second gate insulating film 22. The second lower region 32a is in contact with the second gate insulating film 22.

The second lower region 32a contains the same material as the first lower region 31a. The second lower region 32a is formed of, for example, the same material as the first lower region 31a.

The second lower region 32a is electrically conductive. The second lower region 32a contains a first metal element and nitrogen (N). The first metal element is, for example, a transition metal element. The first metal element is, for example, at least one metal element selected from a group consisting of titanium (Ti), tantalum (Ta), vanadium (V), chromium (Cr), zirconium (Zr), niobium (Nb), hafnium (Hf), and tungsten (W).

The second lower region 32a contains, for example, titanium nitride, tantalum nitride, vanadium nitride, chromium nitride, zirconium nitride, niobium nitride, hafnium nitride, or tungsten nitride. The second lower region 32a is, for example, a titanium nitride, a tantalum nitride, a vanadium nitride, a chromium nitride, a zirconium nitride, a niobium nitride, a hafnium nitride, or a tungsten nitride.

The thickness of the second lower region 32a is, for example, equal to or more than 1 nm and equal to or less than 5 nm.

The second lower region 32a is a region having a dominant effect on the threshold voltage of the p-channel MOSFET 100b.

The second intermediate region 32b is provided between the second upper region 32c and the second lower region 32a. The second intermediate region 32b is provided on the second lower region 32a. The second intermediate region 32b is in contact with, for example, the second lower region 32a. The second intermediate region 32b is provided between the second lower region 32a and the barrier region 32e.

The second intermediate region 32b is electrically conductive. The second intermediate region 32b contains a different material from the second lower region 32a.

The second intermediate region 32b contains the same material as the first intermediate region 31b. The second intermediate region 32b is formed of, for example, the same material as the first intermediate region 31b.

The second intermediate region 32b contains a third metal element and nitrogen (N). The third metal element is different from the first metal element and the second metal element. The third metal element is, for example, a transition metal element. The third metal element is, for example, at least one metal element selected from a group consisting of titanium (Ti), tantalum (Ta), vanadium (V), chromium (Cr), zirconium (Zr), niobium (Nb), hafnium (Hf), and tungsten (W).

The second intermediate region 32b contains, for example, titanium nitride, tantalum nitride, vanadium nitride, chromium nitride, zirconium nitride, niobium nitride, hafnium nitride, or tungsten nitride. The second intermediate region 32b is, for example, a titanium nitride, a tantalum nitride, a vanadium nitride, a chromium nitride, a zirconium nitride, a niobium nitride, a hafnium nitride, or a tungsten nitride.

The thickness of the second intermediate region 32b is, for example, equal to or more than 1 nm and equal to or less than 5 nm.

The barrier region 32e is provided between the second upper region 32c and the second lower region 32a. The barrier region 32e is provided between the second upper region 32c and the second intermediate region 32b. The barrier region 32e is provided on the second intermediate region 32b. The barrier region 32e is in contact with, for example, the second intermediate region 32b.

The barrier region 32e is electrically conductive. The barrier region 32e contains, for example, a different material from the second lower region 32a, the second intermediate region 32b, and the second upper region 32c.

The barrier region 32e contains nitrogen (N) and at least one second metal element of hafnium (Hf) and zirconium (Zr). The second metal element is different from, for example, the third metal element contained in the second intermediate region 32b.

The barrier region 32e contains, for example, hafnium nitride or zirconium nitride. The barrier region 32e is, for example, a hafnium nitride or a zirconium nitride.

The atomic concentration of nitrogen (N) contained in the barrier region 32e is, for example, equal to or more than 1 time and equal to or less than 1.3 times the atomic concentration of at least one of the second metal elements contained in the barrier region 32e. The atomic concentration of nitrogen (N) contained in the barrier region 32e is, for example, equal to or more than 1.1 times and equal to or less than 1.3 times the atomic concentration of at least one of the second metal elements contained in the barrier region 32e.

The thickness of the barrier region 32e is, for example, equal to or more than 1 nm and equal to or less than 10 nm. The thickness of the barrier region 32e is larger than, for example, the thickness of the second lower region 32a and the thickness of the second intermediate region 32b.

The barrier region 32e has, for example, a function of suppressing an increase in the threshold voltage of the p-channel MOSFET 100b by suppressing the movement of nitrogen atoms or aluminum atoms in the second gate electrode 32 during the manufacture of the p-channel MOSFET 100b.

The second upper region 32c is provided between the barrier region 32e and the second metal region 32d. The second upper region 32c is provided on the barrier region 32e. The second upper region 32c is in contact with, for example, the barrier region 32e.

The second upper region 32c is electrically

conductive. The second upper region 32c contains a different material from the second lower region 32a and the second intermediate region 32b.

The second upper region 32c contains the same material as the first upper region 31c. The second upper region 32c is formed of, for example, the same material as the first upper region 31c.

The second upper region 32c contains titanium (Ti) and aluminum (Al). The second upper region 32c contains, for example, a titanium-aluminum alloy.

The thickness of the second upper region 32c is, for example, equal to or more than 1 nm and equal to or less than 8 nm.

The second metal region 32d is provided on the second upper region 32c. The second metal region 32d is in contact with, for example, the second upper region 32c. The second upper region 32c is provided between the barrier region 32e and the second metal region 32d.

The second metal region 32d is electrically conductive. The electric resistivity of the second metal region 32d is smaller than, for example, the electric resistivity of the second lower region 32a, the electric resistivity of the second intermediate region 32b, and the electric resistivity of the second upper region 32c.

The second metal region 32d contains the same material as the first metal region 31d. The second metal region 32d is formed of, for example, the same material as the first metal region 31d.

The second metal region 32d contains a first metal. The first metal is, for example, at least one metal selected from a group consisting of aluminum (Al), tungsten (W), and molybdenum (Mo).

The second metal region 32d may have, for example, a stacked structure of a barrier metal film and a metal film. The barrier metal film is, for example, a titanium nitride. The metal film is, for example, aluminum, tungsten, or molybdenum.

The second metal region 32d has a function of reducing the gate resistance of the p-channel MOSFET 100b, for example.

Next, an example of a method for manufacturing the semiconductor device according to the first embodiment will be described. An example of the method for manufacturing the CMOS semiconductor device 100 according to the first embodiment is a manufacturing method known as a so-called gate-last method. In the gate-last manufacturing method, a source/drain region is formed after a dummy gate electrode is formed. Then, after the source/drain region is formed, the dummy gate electrode is removed and replaced with a gate electrode.

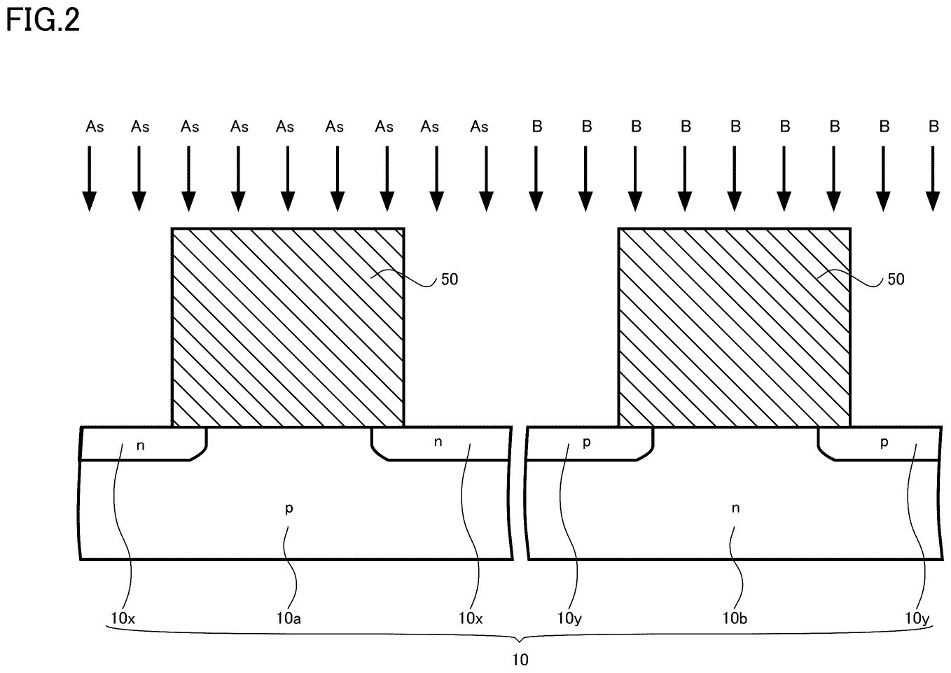

FIGS. 2 to 7 are diagrams showing a method for manufacturing the semiconductor device according to the first embodiment. FIGS. 2 to 7 show cross sections corresponding to FIG. 1.

Hereinafter, an example will be described in which the first gate insulating film 21 and the second gate insulating film 22 are formed of hafnium oxide, the first lower region 31a and the second lower region 32a are formed of titanium nitride, the first intermediate region 31b and the second intermediate region 32b are formed of tantalum nitride, the first upper region 31c and the second upper region 32c are formed of a titanium-aluminum alloy, the first metal region 31d and the second metal region 32d are a stacked structure of titanium nitride and aluminum, and the barrier region 32e is formed of hafnium nitride.

First, the silicon substrate 10 is prepared. Then, the p-well region 10a and the n-well region 10b are formed in the silicon substrate 10. The p-well region 10a and the n-well region 10b are formed by using, for example, a lithography method, an ion implantation method, and a heat treatment.

Then, a dummy gate electrode 50 is formed on the silicon substrate 10. The dummy gate electrode 50 is formed of, for example, polycrystalline silicon. The dummy gate electrode 50 is formed by using, for example, a chemical vapor deposition (CVD) method, a lithography method, and a reactive ion etching (RIE) method. Then, ion implantation is performed using the dummy

gate electrode 50 as a mask. Arsenic (As) ions are implanted into the p-well region 10a, and boron (B) ions are implanted into the n-well region 10b. Thereafter, a heat treatment is performed to activate arsenic (As) and boron (B), thereby forming the first source/drain region 10x of n-type and the second source/drain region 10y of p-type (FIG. 2).

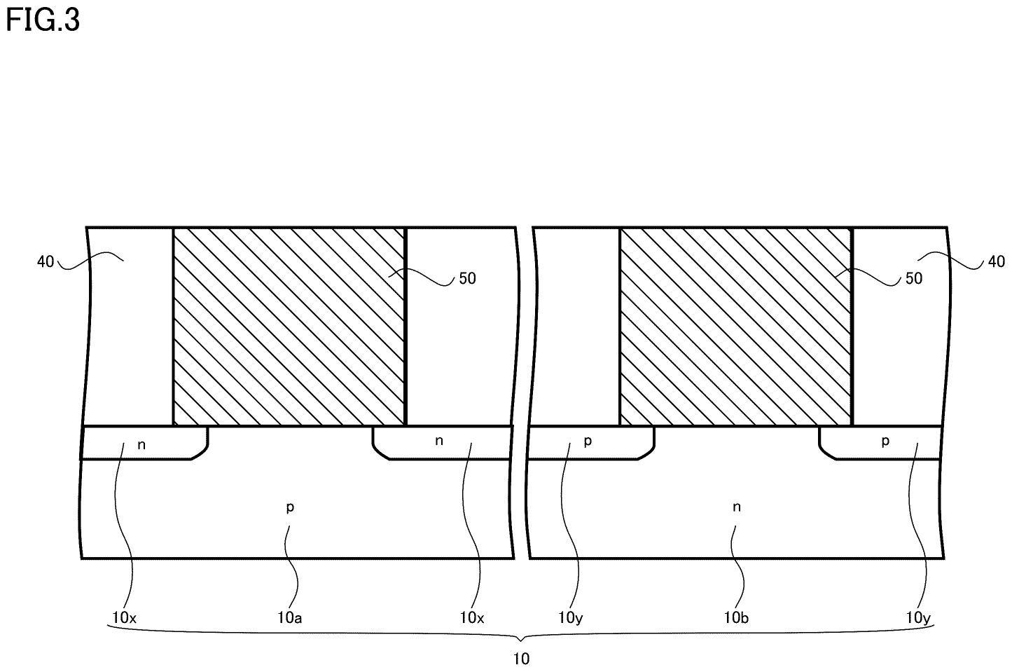

Then, the interlayer insulating layer 40 is formed on the side surfaces of the dummy gate electrode 50 (FIG. 3). The interlayer insulating layer 40 is, for example, a silicon oxide. The interlayer insulating layer 40 is formed by using, for example, a CVD method and a chemical mechanical polishing (CMP) method.

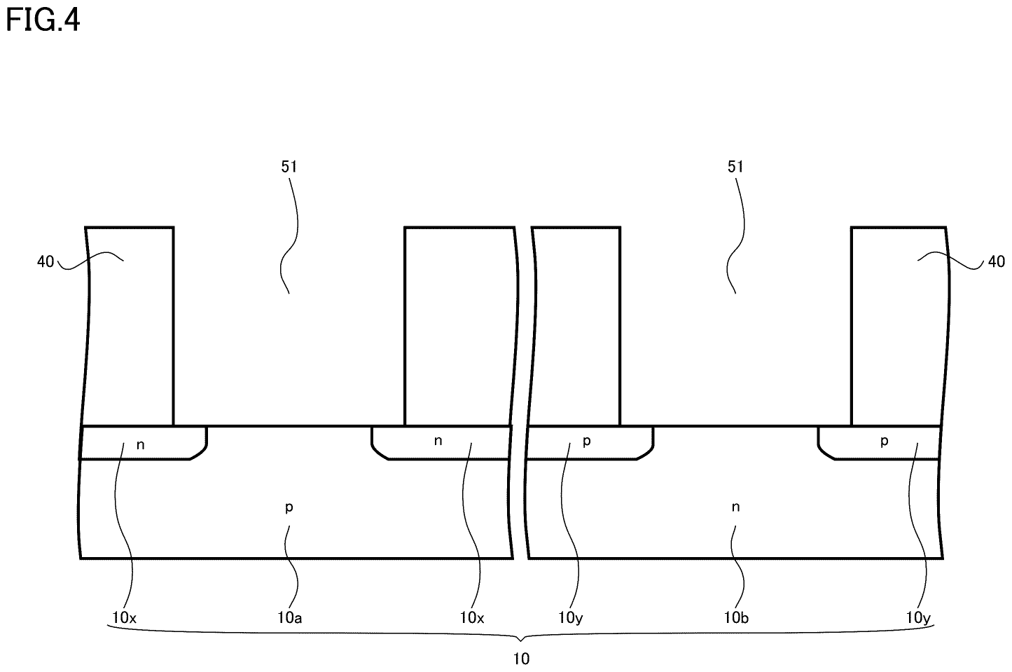

Then, the dummy gate electrode 50 is removed to form a groove 51 in the interlayer insulating layer 40 (FIG. 4). The dummy gate electrode 50 is removed by using, for example, a wet etching method.

Then, a hafnium oxide film 52 is formed in the groove 51. The hafnium oxide film 52 is formed by using, for example, an atomic layer deposition (ALD) method. The hafnium oxide film 52 eventually becomes the first gate insulating film 21 and the second gate insulating film 22.

In addition, before forming the hafnium oxide film 52, a silicon oxide film (not shown) may be formed on the surface of the silicon substrate 10. The silicon oxide film is formed, for example, by thermally oxidizing the surface of the silicon substrate 10.

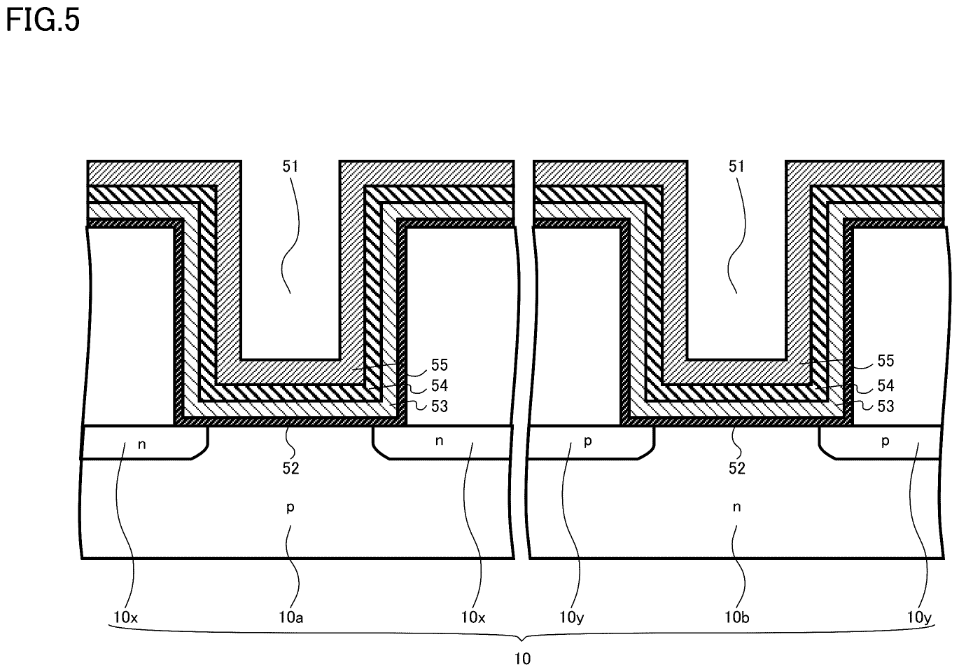

Then, a titanium nitride film 53, a tantalum nitride film 54, and a hafnium nitride film 55 are formed on the hafnium oxide film 52 (FIG. 5). The titanium nitride film 53, the tantalum nitride film 54, and the hafnium nitride film 55 are formed by using, for example, the ALD method. The titanium nitride film 53 eventually becomes the first lower region 31a and the second lower region 32a. The tantalum nitride film 54 eventually becomes the first intermediate region 31b and the second intermediate region 32b. The hafnium nitride film 55 eventually becomes the barrier region 32e.

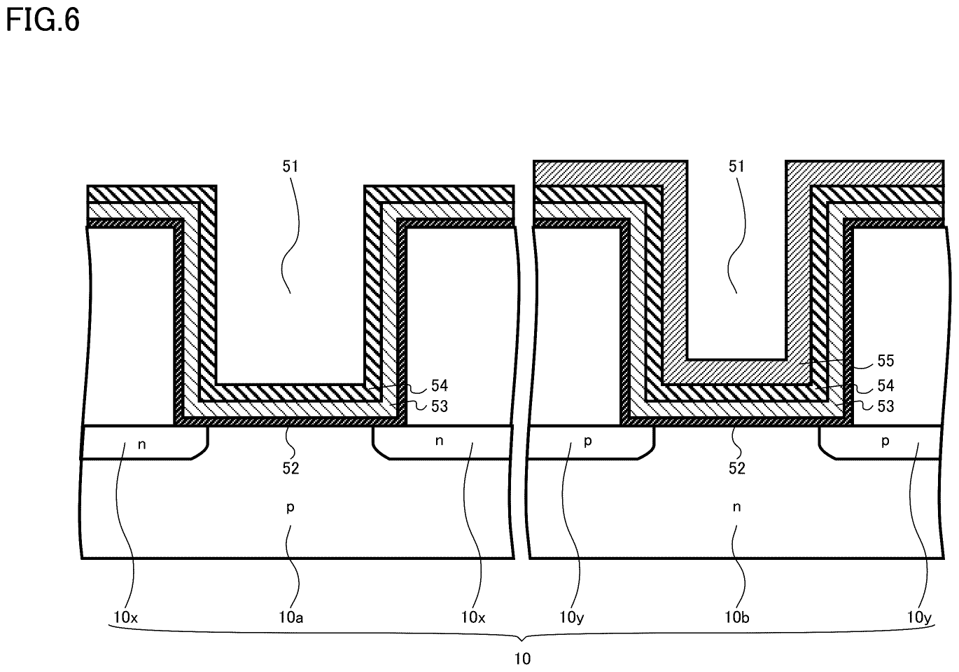

Then, the hafnium nitride film 55 formed in the groove 51 on the p-well region 10a is removed. The hafnium nitride film 55 formed in the groove 51 on the n-well region 10b remains (FIG. 6). The hafnium nitride film 55 is removed by using, for example, a lithography method and a wet etching method.

When removing the hafnium nitride film 55 formed in the groove 51 on the p-well region 10a, the tantalum nitride film 54 functions as an etching stopper film.

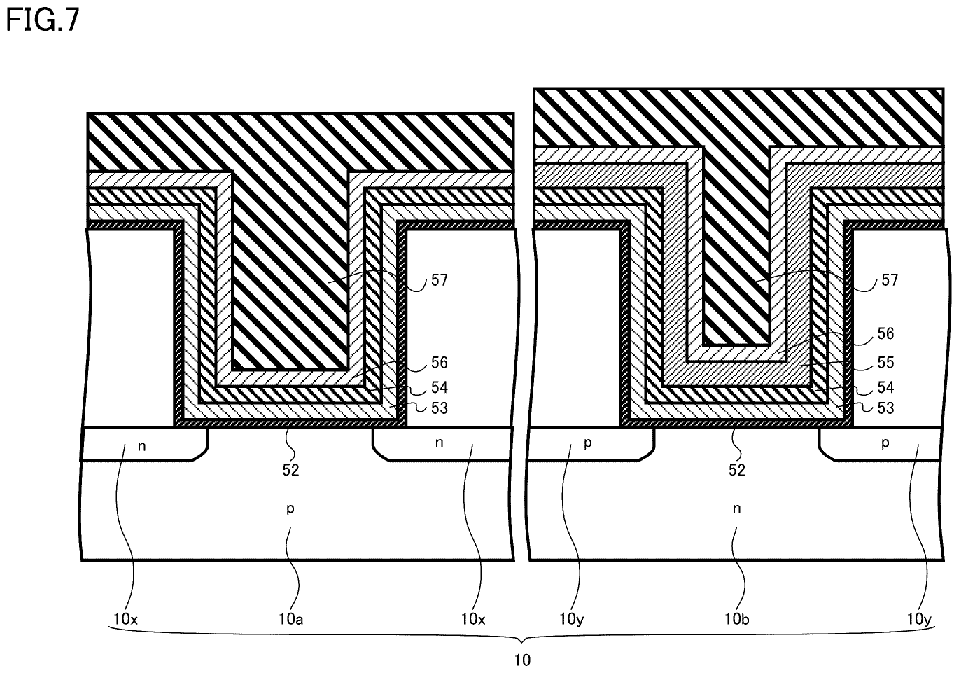

Then, a titanium-aluminum alloy film 56 is formed on the tantalum nitride film 54 and the hafnium nitride film 55. In addition, a stacked film 57 of titanium nitride and aluminum is formed on the titanium-aluminum alloy film 56 (FIG. 7). The titanium-aluminum alloy film 56 is formed by using, for example, the ALD method. The stacked film 57 of titanium nitride and aluminum is formed by using, for example, the CVD method.

Then, the hafnium oxide film 52, the titanium nitride film 53, the tantalum nitride film 54, the hafnium nitride film 55, the titanium-aluminum alloy film 56, and the stacked film 57 on the interlayer insulating layer 40 are removed. The hafnium oxide film 52, the titanium nitride film 53, the tantalum nitride film 54, the hafnium nitride film 55, the titanium-aluminum alloy film 56, and the stacked film 57 are removed by using, for example, the chemical mechanical polishing (CMP) method.

By the manufacturing method described above, the CMOS semiconductor device 100 shown in FIG. 1 is manufactured.

Next, the function and effect of the semiconductor device according to the first embodiment will be described.

In a semiconductor device including an n-channel MOSFET and a p-channel MOSFET, it is desirable to control the threshold voltage of the n-channel MOSFET and the threshold voltage of the p-channel MOSFET to desired values.

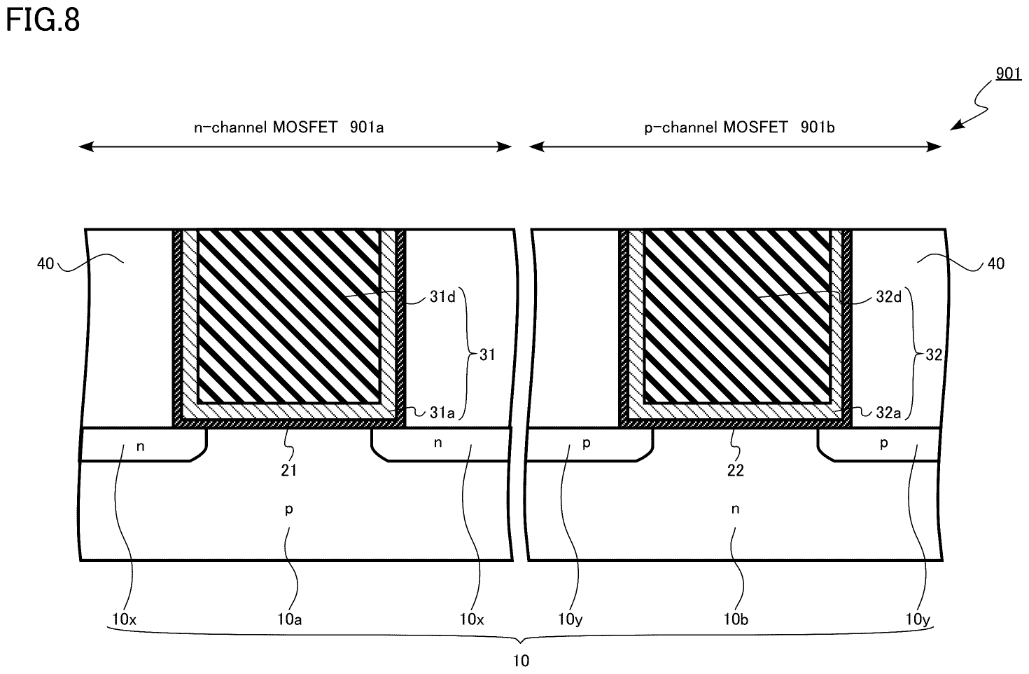

FIG. 8 is a schematic cross-sectional view of a semiconductor device according to a first comparative example. The semiconductor device according to the first comparative example is a CMOS semiconductor device 901. The CMOS semiconductor device 901 includes an n-channel MOSFET 901a and a p-channel MOSFET 901b.

The CMOS semiconductor device 901 is different from the CMOS semiconductor device 100 according to the first embodiment in that the first gate electrode 31 of the n-channel MOSFET 901a includes only the first lower region 31a and the first metal region 31d and the second gate electrode 32 of the p-channel MOSFET 901b includes only the second lower region 32a and the second metal region 32d.

In the CMOS semiconductor device 901 according to the first comparative example, for example, a case will be considered in which the first gate insulating film 21 and the second gate insulating film 22 are hafnium oxide films and the first lower region 31a and the second lower region 32a are titanium nitride regions. In this case, the threshold voltage of the n-channel MOSFET 901a is higher than a desired threshold voltage Vthn. On the other hand, the threshold voltage of the p-channel MOSFET 901b is a desired threshold voltage Vthp. Vthn is, for example, in the range of 0.2 V to 0.4 V, and Vthp is, for example, in the range of −0.2 V to −0.4 V.

In the CMOS semiconductor device 901, it is thought that the work function of the titanium nitride forming the first lower region 31a and the second lower region 32a has a dominant effect on the threshold voltage of the n-channel MOSFET 901a and the threshold voltage of the p-channel MOSFET 901b.

In the following description, a high threshold voltage means that the absolute value of the threshold voltage is large. In addition, a low threshold voltage means that the absolute value of the threshold voltage is small.

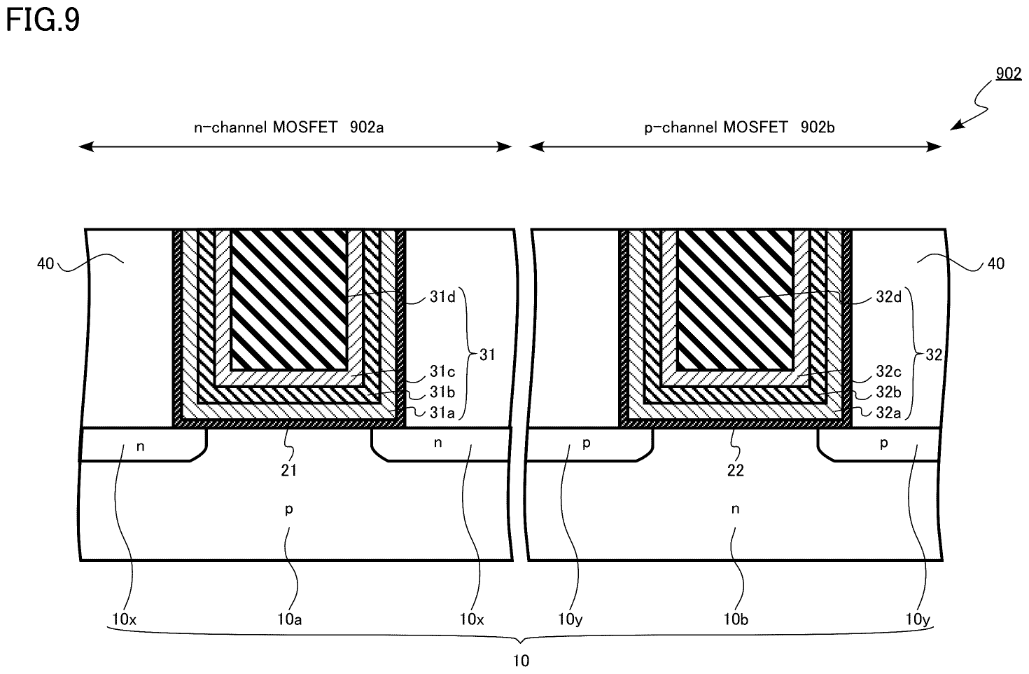

FIG. 9 is a schematic cross-sectional view of a semiconductor device according to a second comparative example. The semiconductor device according to the second comparative example is a CMOS semiconductor device 902. The CMOS semiconductor device 902 includes an n-channel MOSFET 902a and a p-channel MOSFET 902b.

The CMOS semiconductor device 902 is different from the CMOS semiconductor device 901 according to the first comparative example in that the first gate electrode 31 of the n-channel MOSFET 902a includes the first intermediate region 31b and the first upper region 31c. In addition, the CMOS semiconductor device 902 is different from the CMOS semiconductor device 901 according to the first comparative example in that the second gate electrode 32 of the p-channel MOSFET 902b includes the second intermediate region 32b and the second upper region 32c.

The CMOS semiconductor device 902 is different from the CMOS semiconductor device 100 according to the first embodiment in that the second gate electrode 32 of the p-channel MOSFET 100b does not include the barrier region 32e.

In the CMOS semiconductor device 902, a case will be considered in which the first gate insulating film 21 and the second gate insulating film 22 are hafnium oxide films, the first lower region 31a and the second lower region 32a are titanium nitride regions, the first intermediate region 31b and the second intermediate region 32b are tantalum nitride regions, and the first upper region 31c and the second upper region 32c are titanium-aluminum alloy regions. In the CMOS semiconductor device 902, the first gate electrode 31 and the second gate electrode 32 have the same stacked structure.

In the CMOS semiconductor device 902 according to the second comparative example, the threshold voltage of the n-channel MOSFET 902a is the desired threshold voltage Vthn. On the other hand, the threshold voltage of the p-channel MOSFET 902b is higher than the desired threshold voltage Vthp. In other words, in the CMOS semiconductor device 902 according to the second comparative example, the threshold voltage of the n-channel MOSFET 902a is lower than the threshold voltage of the n-channel MOSFET 901a of the CMOS semiconductor device 901 according to the first comparative example. On the other hand, the threshold voltage of the p-channel MOSFET 902b is higher than the threshold voltage Vthp of the p-channel MOSFET 901b of the CMOS semiconductor device 901 according to the first comparative example.

The reason why, in the CMOS semiconductor device 902, the threshold voltage of the n-channel MOSFET is lower and the threshold voltage of the p-channel MOSFET is higher than in the CMOS semiconductor device 901 is thought that the effective work function of the gate electrode changes due to the movement of atoms in the gate electrode.

The effective work function is different from the work function, which is a value specific to a material. The work function is an energy difference between the vacuum level and the Fermi level. The effective work function means a work function obtained by actually electrically measuring the MOS structure. For example, the effective work function is a value that can be changed by changing the stacked structure of the gate electrode.

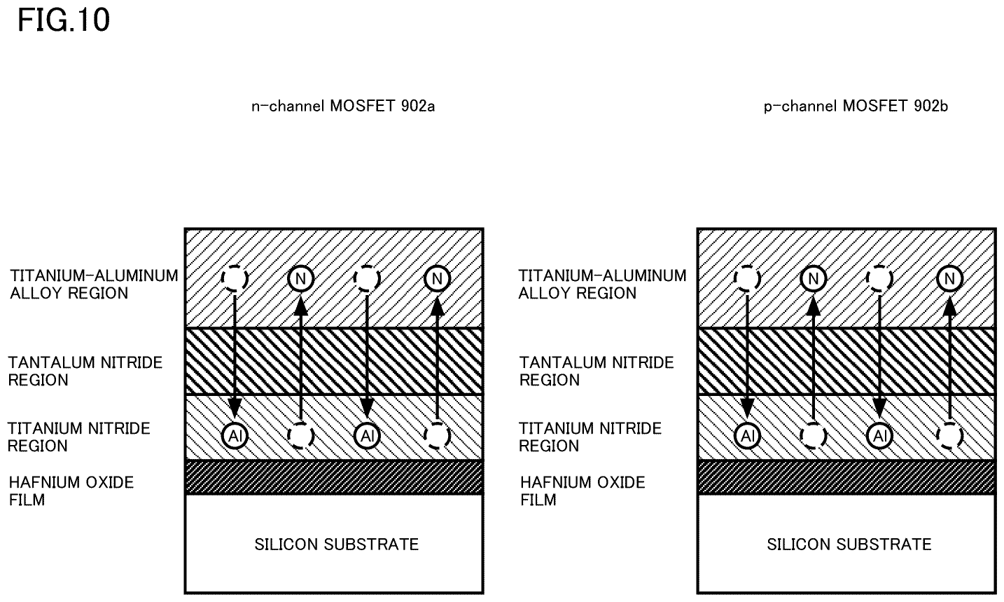

FIG. 10 is an explanatory diagram of the function and effect of the semiconductor device according to the first embodiment. FIG. 10 is an enlarged schematic cross-sectional view including a part (left) of the first gate electrode 31 of the n-channel MOSFET 902a and a part (right) of the second gate electrode 32 of the p-channel MOSFET 902b in the CMOS semiconductor device 902 according to the second comparative example.

FIG. 10 schematically shows the movement of nitrogen atoms and aluminum atoms in a gate electrode. As shown in FIG. 10, it is thought that nitrogen atoms or aluminum atoms move through the gate electrode due to the heat treatment applied during the manufacture of the CMOS semiconductor device 902.

For example, nitrogen atoms contained in the titanium nitride region move to the titanium-aluminum alloy region, decreasing the nitrogen concentration in the titanium nitride region. In addition, for example, aluminum atoms in the titanium-aluminum alloy region move to the titanium nitride region, increasing the aluminum concentration in the titanium nitride region. The titanium-aluminum alloy region functions as a nitrogen absorber. In addition, the titanium-aluminum alloy region functions as an aluminum emission source.

It is thought that the effective work function of the gate electrode decreases when the nitrogen concentration in the titanium nitride region decreases or the aluminum concentration in the titanium nitride region increases. It is thought that, as the effective work function of the gate electrode decreases, the threshold voltage of the n-channel MOSFET 902a decreases and the threshold voltage of the p-channel MOSFET 902b increases.

In the CMOS semiconductor device 100 according to the first embodiment, the second gate electrode 32 of the p-channel MOSFET 100b includes the barrier region 32e. In the CMOS semiconductor device 100 according to the first embodiment, the threshold voltage of the n-channel MOSFET 100a is the desired threshold voltage Vthn. In addition, the threshold voltage of the p-channel MOSFET 100b is also the desired threshold voltage Vthp.

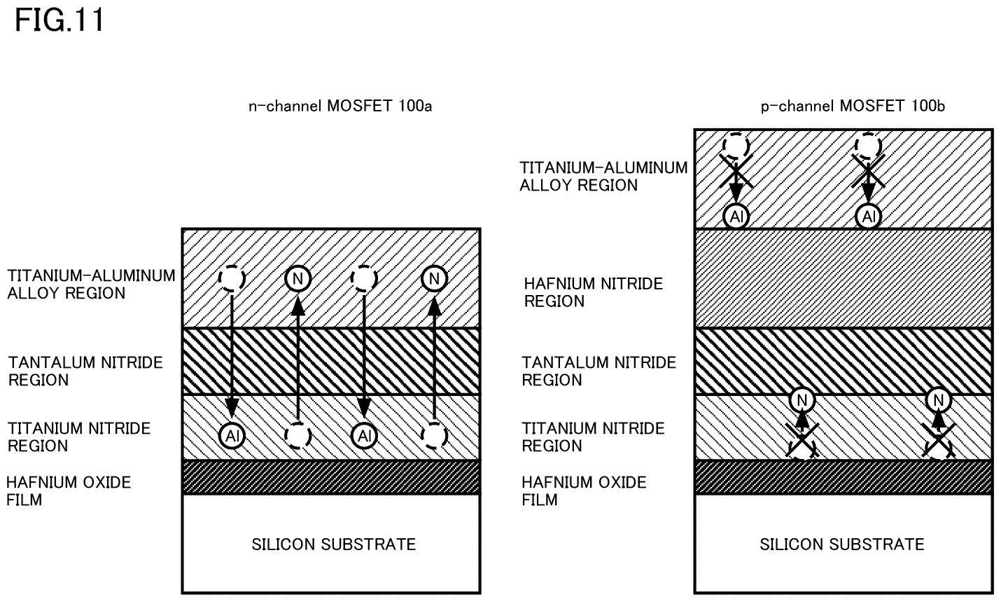

FIG. 11 is an explanatory diagram of the function and effect of the semiconductor device according to the first embodiment. FIG. 11 is an enlarged schematic cross- sectional view including a part (left) of the first gate electrode 31 of the n-channel MOSFET 100a and a part (right) of the second gate electrode 32 of the p-channel MOSFET 100b in the CMOS semiconductor device 100 according to the first embodiment. FIG. 11 is a diagram corresponding to FIG. 10.

In the CMOS semiconductor device 100, the second gate electrode 32 of the p-channel MOSFET 100b includes a hafnium nitride region that is the barrier region 32e. As shown in FIG. 11, it is thought that the movement of nitrogen atoms and aluminum atoms in the gate electrode is suppressed by providing the hafnium nitride region. Therefore, it is thought that a decrease in nitrogen concentration in the titanium nitride region or an increase in aluminum concentration in the titanium nitride region as in the gate electrode of the n-channel MOSFET 100a is suppressed. Therefore, it is thought that the threshold voltage of the p-channel MOSFET 100b is the desired threshold voltage Vthp, like the p-channel MOSFET 901b in the first comparative example.

The reason why the movement of nitrogen atoms in the gate electrode is suppressed when the barrier region 32e contains hafnium nitride is thought that nitrogen atoms are unlikely to escape because the generation energy for nitrogen vacancies in hafnium nitride is high. For example, hafnium nitride has a higher nitrogen vacancy generation energy than titanium nitride.

In addition, the reason why the movement of aluminum atoms in the gate electrode is suppressed when the barrier region 32e contains hafnium nitride is thought that aluminum is unlikely to exist in hafnium nitride because the generation energy required to substitute hafnium in hafnium nitride with aluminum is high. For example, hafnium nitride has a higher generation energy for aluminum substitution of metal elements than titanium nitride.

Similarly to hafnium nitride, zirconium nitride has a higher nitrogen vacancy generation energy than titanium nitride. In addition, similarly to hafnium nitride, zirconium nitride has a higher generation energy for aluminum substitution of metal elements than titanium nitride. Therefore, it is thought that the movement of nitrogen atoms and aluminum atoms in the gate electrode is suppressed because the barrier region 32e contains zirconium nitride.

In the CMOS semiconductor device 100 according to the first embodiment, it is possible to control the threshold voltage of the n-channel MOSFET 100a and the threshold voltage of the p-channel MOSFET 100b to desired threshold voltages.

From the viewpoint of suppressing an increase in the threshold voltage of the p-channel MOSFET 100b, the thickness of the barrier region 32e is preferably equal to or more than 1 nm, more preferably equal to or more than 3 nm, and even more preferably equal to or more than 5 nm.

From the viewpoint of suppressing an increase in the threshold voltage of the p-channel MOSFET 100b, the thickness of the barrier region 32e is preferably larger than the thickness of the second lower region 32a and the thickness of the second intermediate region 32b.

From the viewpoint of suppressing an increase in the threshold voltage of the p-channel MOSFET 100b, the atomic concentration of nitrogen (N) contained in the barrier region 32e is preferably equal to or more than 1 time, more preferably equal to or more than 1.1 times, and even more preferably equal to or more than 1.2 times the atomic concentration of the second metal element contained in the barrier region 32e.

From the viewpoint of lowering the threshold voltage of the n-channel MOSFET 100a, the thickness of the first upper region 31c is preferably equal to or more than 1 nm, more preferably equal to or more than 3 nm, and even more preferably equal to or more than 5 nm.

As described above, according to the semiconductor device according to the first embodiment, it is possible to provide a semiconductor device in which the threshold voltage of the n-channel MOSFET and the threshold voltage of the p-channel MOSFET are controlled to desired threshold voltages.

### Second Embodiment

A semiconductor device according to a second embodiment is different from the semiconductor device according to the first embodiment in that the first gate electrode does not include the sixth region and the second gate electrode does not include the seventh region. Hereinafter, the description of a part of the content overlapping the first embodiment will be omitted.

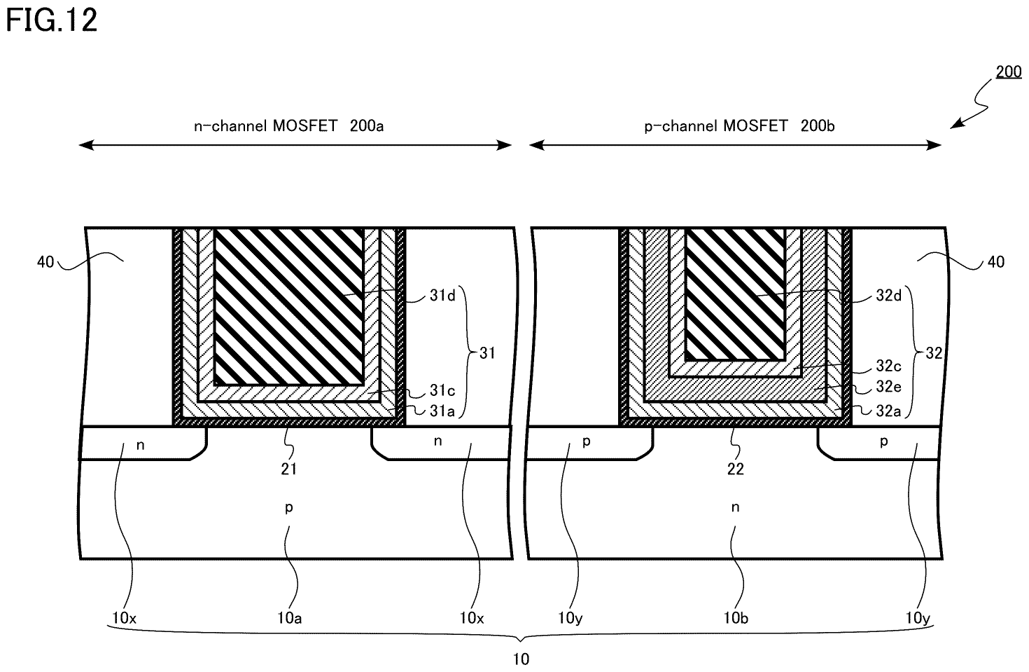

FIG. 12 is a schematic cross-sectional view of the semiconductor device according to the second embodiment. The semiconductor device according to the second embodiment is a CMOS semiconductor device 200.

The CMOS semiconductor device 200 includes an n-channel MOSFET 200a and a p-channel MOSFET 200b. The n-channel MOSFET 200a is a field effect transistor that uses electrons as carriers. The p-channel MOSFET 200b is a field effect transistor that uses holes as carriers. In addition, the n-channel MOSFET 200a and the p-channel MOSFET 200b use a so-called metal gate electrode in which a metal material is used for a gate electrode.

The CMOS semiconductor device 200 includes a CMOS circuit formed by the n-channel MOSFET 200a and the p-channel MOSFET 200b. The CMOS semiconductor device 200 includes, for example, a plurality of n-channel MOSFETs 200a and a plurality of p-channel MOSFETs 200b.

The n-channel MOSFET 200a includes a silicon substrate 10, a first gate insulating film 21, a first gate electrode 31, and an interlayer insulating layer 40. The silicon substrate 10 includes a p-well region 10a and a first source/drain region 10x. The first gate electrode 31 includes a first lower region 31a, a first upper region 31c, and a first metal region 31d.

The silicon substrate 10 is an example of a semiconductor substrate. The first lower region 31a is an example of the second region. The first upper region 31c is an example of the first region.

The p-channel MOSFET 200b includes the silicon substrate 10, a second gate insulating film 22, a second gate electrode 32, and the interlayer insulating layer 40. The silicon substrate 10 includes an n-well region 10b and a second source/drain region 10y. The second gate electrode 32 includes a second lower region 32a, a second upper region 32c, a second metal region 32d, and a barrier region 32e.

The second lower region 32a is an example of the fourth region. The second upper region 32c is an example of the third region. The barrier region 32e is an example of the fifth region.

The first upper region 31c is provided on the first lower region 31a. The first upper region 31c is in contact with the first lower region 31a.

The barrier region 32e is provided on the second lower region 32a. The barrier region 32e is in contact with the second lower region 32a.

The first lower region 31a and the second lower region 32a contain a first metal element and nitrogen (N). In addition, the barrier region 32e contains nitrogen (N) and at least one second metal element of hafnium (Hf) and zirconium (Zr).

In the CMOS semiconductor device 100 according to the first embodiment, the first intermediate region 31b functions as an etching stopper film when removing a film, which becomes the barrier region 32e of the p-channel MOSFET 100b, from the first gate electrode 31 during the manufacture of the n-channel MOSFET 100a. When the first lower region 31a functions as an etching stopper film when removing a film to become the barrier region 32e of the second gate electrode 32 from the first gate electrode 31, it is possible to omit the first intermediate region 31b and the second intermediate region 32b of the CMOS semiconductor device 100, as in the CMOS semiconductor device 200 according to the second embodiment.

As described above, according to the semiconductor device according to the second embodiment, as in the semiconductor device according to the first embodiment, it is possible to provide a semiconductor device in which the threshold voltage of the n-channel MOSFET and the threshold voltage of the p-channel MOSFET are controlled to desired threshold voltages.

### Third Embodiment

A semiconductor device according to a third embodiment is different from the semiconductor device according to the first embodiment in that the semiconductor device according to the third embodiment is manufactured using a manufacturing method known as a so-called gate-first method. Hereinafter, the description of a part of the content overlapping the first embodiment will be omitted.

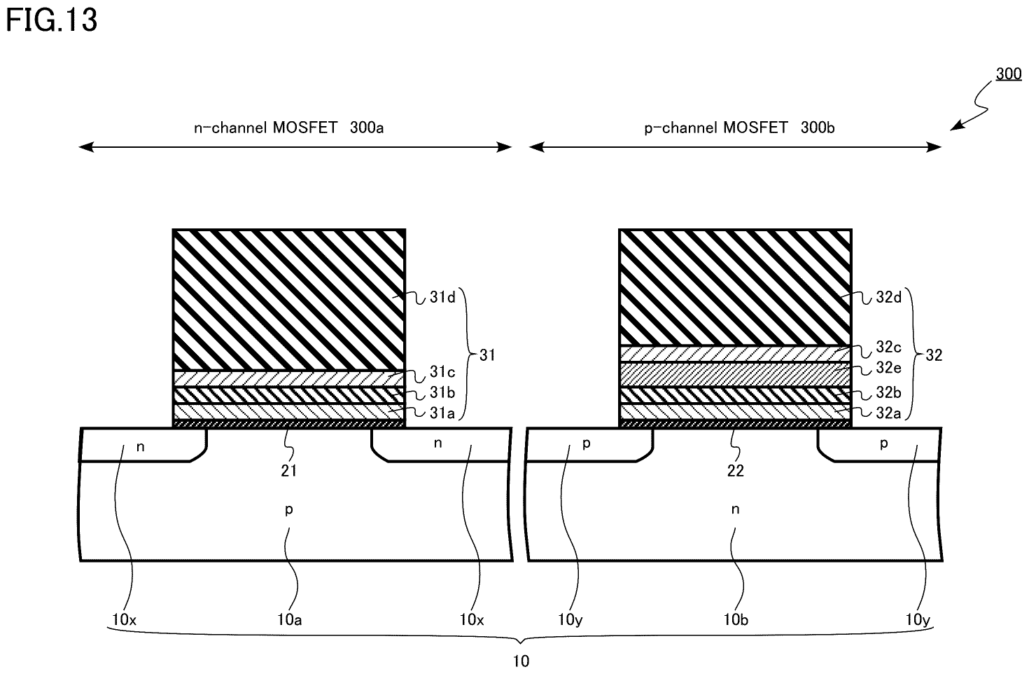

FIG. 13 is a schematic cross-sectional view of the semiconductor device according to the third embodiment. The semiconductor device according to the third embodiment is a CMOS semiconductor device 300.

The CMOS semiconductor device 300 includes an n-channel MOSFET 300a and a p-channel MOSFET 300b. The n-channel MOSFET 300a is a field effect transistor that uses electrons as carriers. The p-channel MOSFET 300b is a field effect transistor that uses holes as carriers. In addition, the n-channel MOSFET 300a and the p-channel MOSFET 300b use a so-called metal gate electrode in which a metal material is used for a gate electrode.

The CMOS semiconductor device 300 includes a CMOS circuit formed by the n-channel MOSFET 300a and the p-channel MOSFET 300b. The CMOS semiconductor device 300 includes, for example, a plurality of n-channel MOSFETS 300a and a plurality of p-channel MOSFETs 300b.

The n-channel MOSFET 300a includes a silicon substrate 10, a first gate insulating film 21, and a first gate electrode 31. The silicon substrate 10 includes a p-well region 10a and a first source/drain region 10x. The first gate electrode 31 includes a first lower region 31a, a first intermediate region 31b, a first upper region 31c, and a first metal region 31d.

The silicon substrate 10 is an example of a semiconductor substrate. The first lower region 31a is an example of the second region. The first intermediate region 31b is an example of the sixth region. The first upper region 31c is an example of the first region.

The p-channel MOSFET 300b includes the silicon substrate 10, a second gate insulating film 22, and a second gate electrode 32. The silicon substrate 10 includes an n-well region 10b and a second source/drain region 10y. The second gate electrode 32 includes a second lower region 32a, a second intermediate region 32b, a second upper region 32c, a second metal region 32d, and a barrier region 32e.

The second lower region 32a is an example of the fourth region. The second intermediate region 32b is an example of the seventh region. The second upper region 32c is an example of the third region. The barrier region 32e is an example of the fifth region.

The CMOS semiconductor device 300 is manufactured using a manufacturing method known as a so-called gate-first method. In the gate-first manufacturing method, the source/drain region is formed after the gate electrode is formed. For example, after the gate electrode is formed using a lithography method and an RIE method, ion implantation is performed using the gate electrode as a mask to form the source/drain region.

As described above, according to the semiconductor device according to the third embodiment, as in the semiconductor device according to the first embodiment, it is possible to provide a semiconductor device in which the threshold voltage of the n-channel MOSFET and the threshold voltage of the p-channel MOSFET are controlled to desired threshold voltages.

### Fourth Embodiment

A semiconductor memory device according to a fourth embodiment includes an n-channel MOSFET including a first gate insulating film and a first gate electrode, a p-channel MOSFET including a second gate insulating film and a second gate electrode, and a memory cell array including a plurality of memory cells. The first gate electrode includes a first region containing titanium (Ti) and aluminum (Al) and a second region provided between the first gate insulating film and the first region, in contact with the first gate insulating film, and containing a first metal element and nitrogen (N). The second gate electrode includes a third region containing titanium (Ti) and aluminum (Al), a fourth region provided between the second gate insulating film and the third region, in contact with the second gate insulating film, and containing the first metal element and nitrogen (N), and a fifth region provided between the third region and the fourth region and containing nitrogen (N) and at least one second metal element of hafnium (Hf) and zirconium (Zr). The semiconductor memory device according to the fourth embodiment is different from the first embodiment in that, in addition to the semiconductor device according to the first embodiment, a memory cell array including a plurality of memory cells is provided. Hereinafter, the description of a part of the content overlapping the first embodiment will be omitted.

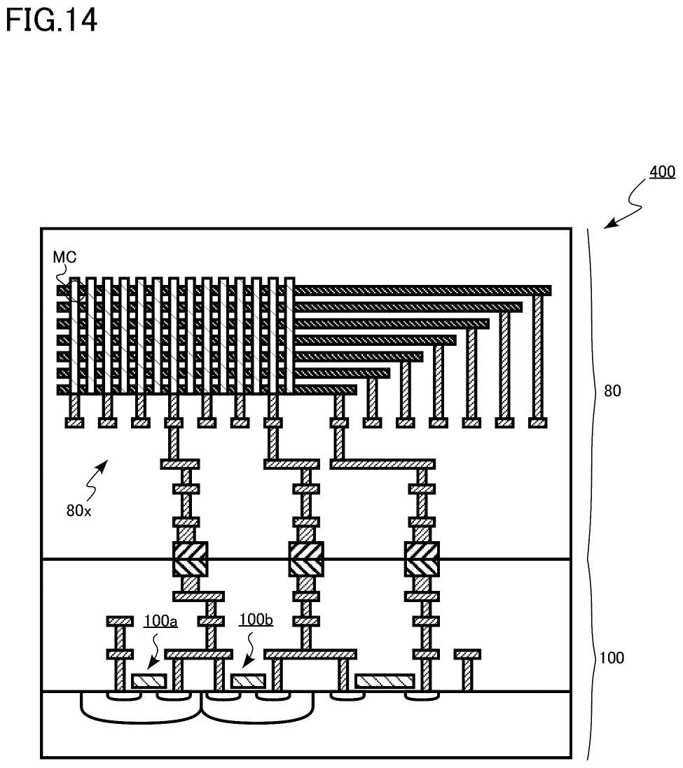

FIG. 14 is a schematic cross-sectional view of the semiconductor memory device according to the fourth embodiment. The semiconductor memory device according to the fourth embodiment is a three-dimensional NAND flash memory 400.

The three-dimensional NAND flash memory 400 includes the CMOS semiconductor device 100 according to the first embodiment and a memory layer 80. The memory layer 80 includes a memory cell array 80x including a plurality of memory cells MC. The plurality of memory cells MC are arranged, for example, three-dimensionally in the memory cell array 80x.

The CMOS semiconductor device 100 and the memory layer 80 are electrically connected to each other using, for example, metal wiring. The CMOS semiconductor device 100 and the memory cell array 80x are electrically connected to each other using, for example, metal wiring.

The n-channel MOSFET 100a and the p-channel MOSFET 100b included in the CMOS semiconductor device 100 control the operations of the plurality of memory cells MC included in the memory cell array 80x.

The three-dimensional NAND flash memory 400 can be manufactured, for example, by bonding the CMOS semiconductor device 100 and the memory layer 80 manufactured separately to each other.

As described above, according to the semiconductor memory device according to the fourth embodiment, it is possible to provide a semiconductor memory device in which the threshold voltage of the n-channel MOSFET and the threshold voltage of the p-channel MOSFET are controlled to desired threshold voltages.

In the first to third embodiments, the silicon substrate has been described as an example of the semiconductor substrate, but it is also possible to use a semiconductor substrate other than the silicon substrate. In the first to third embodiments, the case where

the n-channel MOSFET 100a and the p-channel MOSFET 100b are formed using the same semiconductor substrate has been described as an example. However, for example, the n-channel MOSFET 100a and the p-channel MOSFET 100b can also be formed using semiconductor layers that are physically separated from each other.

In the fourth embodiment, a semiconductor memory device including the CMOS semiconductor device 100 according to the first embodiment has been described as an example. However, the semiconductor memory device according to the fourth embodiment may be a semiconductor memory device including the CMOS semiconductor device according to the second or third embodiment.

In the fourth embodiment, a three-dimensional NAND flash memory has been described as an example, but the semiconductor memory device may be, for example, other semiconductor memory devices such as a dynamic random access memory (DRAM) and a resistance change memory.

While certain embodiments have been described, these embodiments have been presented by way of example only, and are not intended to limit the scope of the inventions. Indeed, the semiconductor device and the semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
an n-channel MOSFET including a first gate insulating film and a first gate electrode, the first gate electrode including a first region and a second region, the second region provided between the first gate insulating film and the first region and in contact with the first gate insulating film, the first region containing titanium (Ti) and aluminum (Al), and the second region containing a first metal element and nitrogen (N); and
a p-channel MOSFET including a second gate insulating film and a second gate electrode, the second gate electrode including a third region, a fourth region, and a fifth region, the fourth region provided between the second gate insulating film and the third region and in contact with the second gate insulating film, the fifth region provided between the third region and the fourth region, the third region containing titanium (Ti) and aluminum (Al), the fourth region containing the first metal element and nitrogen (N), and the fifth region containing nitrogen (N) and a second metal element being at least one of hafnium (Hf) and zirconium (Zr).

2. The semiconductor device according to claim 1,
wherein the first metal element and the second metal element are different.

3. The semiconductor device according to claim 1,
wherein the first gate electrode further includes a sixth region provided between the first region and the second region and containing a third metal element and nitrogen (N), the third metal element being different from the first metal element and the second metal element, and
the second gate electrode further includes a seventh region provided between the fourth region and the fifth region and containing the third metal element and nitrogen (N).

4. The semiconductor device according to claim 1,
wherein the first metal element is a transition metal element.

5. The semiconductor device according to claim 4,
wherein the first metal element is at least one metal element selected from a group consisting of titanium (Ti), tantalum (Ta), vanadium (V), chromium (Cr), zirconium (Zr), niobium (Nb), hafnium (Hf), and tungsten (W).

6. The semiconductor device according to claim 3,
wherein the third metal element is a transition metal element.

7. The semiconductor device according to claim 6,
wherein the third metal element is at least one metal element selected from a group consisting of titanium (Ti), tantalum (Ta), vanadium (V), chromium (Cr), zirconium (Zr), niobium (Nb), hafnium (Hf), and tungsten (W).

8. The semiconductor device according to claim 1,
wherein the first gate insulating film and the second gate insulating film contain a material having a higher dielectric constant than silicon dioxide.

9. The semiconductor device according to claim 1,
wherein the first gate insulating film and the second gate insulating film contain oxygen (0) and at least one element selected from a group consisting of hafnium (Hf), zirconium (Zr), tantalum (Ta), yttrium (Y), and titanium (Ti).

10. The semiconductor device according to claim 1,
wherein the n-channel MOSFET further includes a first portion of a semiconductor substrate, and the first gate insulating film is provided on the first portion, and
the p-channel MOSFET further includes a second portion of the semiconductor substrate, and the second gate insulating film is provided on the second portion.

11. The semiconductor device according to claim 1,
wherein the first gate electrode further includes a first metal region containing a first metal,
the second gate electrode further includes a second metal region containing the first metal,
the first region is provided between the second region and the first metal region, the third region is provided between the fifth region and the second metal region, and
the first metal is at least one metal selected from a group consisting of aluminum (Al), tungsten (W), and molybdenum (Mo).

12. The semiconductor device according to claim 1,
wherein an atomic concentration of nitrogen (N) contained in the fifth region is equal to or more than 1 time and equal to or less than 1.3 times an atomic concentration of the second metal element contained in the fifth region.

13. The semiconductor device according to claim 3,
wherein a thickness of the fifth region is larger than a thickness of the fourth region and larger than a thickness of the seventh region.

14. The semiconductor device according to claim 3,
wherein the first metal element is titanium (Ti), and the third metal element is tantalum (Ta).

15. A semiconductor memory device, comprising:
an n-channel MOSFET including a first gate insulating film and a first gate electrode, the first gate electrode including a first region and a second region, the second region provided between the first gate insulating film and the first region and in contact with the first gate insulating film, the first region containing titanium (Ti) and aluminum (Al), and the second region containing a first metal element and nitrogen (N);
a p-channel MOSFET including a second gate insulating film and a second gate electrode, the second gate electrode including a third region, a fourth region, and a fifth region, the fourth region provided between the second gate insulating film and the third region and in contact with the second gate insulating film, the fifth region provided between the third region and the fourth region, the third region containing titanium (Ti) and aluminum (Al), the fourth region containing the first metal element and nitrogen (N), and the fifth region containing nitrogen (N) and a second metal element being at least one of hafnium (Hf) and zirconium (Zr); and
a memory cell array including a plurality of memory cells.

16. The semiconductor memory device according to claim 15,
wherein the n-channel MOSFET and the p-channel MOSFET control operations of the plurality of memory cells.

17. The semiconductor memory device according to claim 15,
wherein the first metal element and the second metal element are different.

18. The semiconductor memory device according to claim 15,
wherein the first gate electrode further includes a sixth region provided between the first region and the second region and containing a third metal element and nitrogen (N), the third metal element being different from the first metal element and the second metal element, and
the second gate electrode further includes a seventh region provided between the fourth region and the fifth region and containing the third metal element and nitrogen (N).

19. The semiconductor memory device according to claim 15,
wherein the first metal element is a transition metal element.

20. The semiconductor memory device according to claim 19,
wherein the first metal element is at least one metal element selected from a group consisting of titanium (Ti), tantalum (Ta), vanadium (V), chromium (Cr), zirconium (Zr), niobium (Nb), hafnium (Hf), and tungsten (W).
